(19) United States
(12) Patent Application Publication
(10) Pub. No.: US 2024/0172547 A1
(43) Pub. Date: May 23, 2024

(54) PROCESS FOR MANUFACTURING AN ORGANIC ELECTROLUMINESCENT DEVICE

(71) Applicant: Commissariat à l'Energie Atomique et aux Energies Alternatives, Paris (FR)

(72) Inventors: Myriam TOURNAIRE, Grenoble Cedex 09 (FR); Tony MAINDRON, Grenoble Cedex 09 (FR)

(73) Assignee: Commissariat à l'Energie Atomique et aux Energies Alternatives, Paris (FR)

(21) Appl. No.: 18/512,193

(22) Filed: Nov. 17, 2023

(30) Foreign Application Priority Data
Nov. 17, 2022 (FR) 22 11969

(51) Int. Cl. H10K 71/60; H10K 59/12

(52) U.S. Cl. CPC H10K 71/60; H10K 59/1201

(57) ABSTRACT

Process for manufacturing an organic electroluminescent device on a stack comprising, in succession:
a substrate, incorporating n-type thin-film transistors each comprising a drain, a source and a gate;
an interconnecting structure, electrically connected to the n-type transistors, and comprising:
a common anode, electrically connected to the sources of the n-type transistors; vias, each electrically connected to a drain of one n-type transistor;
the organic electroluminescent device being formed with a direct architecture, a cathode being singulated at the pixel scale, each pixel being drivable using an electrical contact pad dedicated thereto.

### TECHNICAL FIELD

The invention relates to the technical field of manufacture of an organic electroluminescent device, in particular an OLED microdisplay (OLED standing for Organic Light-Emitting Diode).

In particular, the invention is applicable to manufacture of virtual-reality or augmented-reality headsets and glasses, camera viewfinders, head-up displays, pico-projectors, etc.

### PRIOR ART

A process for manufacturing an organic electroluminescent device known in the prior art, and in particular from the document by H.-H. Hsieh et al., “A 2.4 in. AMOLED with IGZO TFTs and inverted OLED devices”, SID, vol. 40, issue 1, 2010, comprises steps of:
a₀₁) using a stack comprising, in succession:
   a substrate, incorporating n-type thin-film transistors each comprising a drain, a source and a gate;
   an interconnecting structure, electrically connected to the n-type transistors, and comprising:
first vias, each being electrically connected to a source of one n-type transistor;
second vias, each being electrically connected to a drain of one n-type transistor;
b₀₁) forming:
   a set of anode layers on the interconnecting structure, these anode layers being spaced apart from one another so as to form a network of rows and of columns, each anode layer being electrically connected to a first via,
   an electrical contact pad on the interconnecting structure, adjacent to the set of anode layers, and electrically connected to the second vias;
c₀₁) forming a set of stacks of organic semiconductor layers, each stack of organic semiconductor layers extending over an anode layer and around said anode layer;
d₀₁) forming a common cathode extending over the interconnecting structure, over the set of stacks of organic semiconductor layers and over the electrical contact pad.

It appears advantageous to use n-type thin-film transistors (TFTs) as the channel may be made of a transparent conducting oxide (TCO) or of a transparent semiconducting oxide (TSO) such as indium-gallium-zinc (In—Ga—Zn) oxide (IGZO). In particular, IGZO exhibits better stability under the current used to drive organic electroluminescent devices such as OLED microdisplays. The TFTs are conventionally arranged so as to form a 2T-1C pixel supply and addressing scheme, i.e. two TFT transistors and one capacitor are used to drive one pixel.

However, this prior-art process is not entirely satisfactory insofar as a drift in V_{GS} voltage (voltage between the gate and source) has been observed, leading to substantial burn-in and to after-images.

A process for manufacturing an organic electroluminescent device known in the prior art, and in particular from the document by H.-H. Hsieh et al., “A 2.4 in. AMOLED with IGZO TFTs and inverted OLED devices”, SID, vol. 40, issue 1, 2010, comprises steps of:
a₀₂) using a stack comprising, in succession:
   a substrate, incorporating n-type thin-film transistors each comprising a drain, a source and a gate;
   an interconnecting structure, electrically connected to the n-type transistors, and comprising:
first vias, each being electrically connected to a source of one n-type transistor;
second vias, each being electrically connected to a drain of one n-type transistor;
b₀₂) forming:
   a set of cathode layers on the interconnecting structure, these cathode layers being spaced apart from one another so as to form a network of rows and of columns, each cathode layer being electrically connected to a first via,
   an electrical contact pad on the interconnecting structure, adjacent to the set of cathode layers, and electrically connected to the second vias;
c₀₂) forming a set of stacks of organic semiconductor layers, each stack of organic semiconductor layers extending over a cathode layer and around said cathode layer;
d₀₂) forming a common anode extending over the interconnecting structure, over the set of stacks of organic semiconductor layers and over the electrical contact pad.

This prior-art process forms the electroluminescent device (i.e. the stacks of semiconductor layers, the cathode layers and the common anode) in reverse, i.e. the anode is located above the cathode in the stack. Such an inverted architecture makes it possible to drastically decrease burn-in.

However, this prior-art process is not entirely satisfactory as it results in a high series resistance due to a problem with carrier injection between the cathode layer and the stack of organic semiconductor layers (and more precisely with the electron injection layer), see J. Wang et al., “Efficient inverted organic light-emitting devices using a charge-generation unit as electron-injection layers”, Organic Electronics, vol. 96, 106202, 2021 and S. Madasamy et al., “An overview about the use of electrical doping of charge carrier transport layers in OLEDs and further organic electronic applications”, Proc. SPIE 6999, Organic Optoelectronics and Photonics III, 69991E, 2008.

### SUMMARY OF THE INVENTION

The invention aims to completely or partially remedy the aforementioned drawbacks. To this end, the subject of the invention is a process for manufacturing an organic electroluminescent device, comprising steps of:
a) using a stack comprising, in succession:
   a substrate, incorporating n-type thin-film transistors each comprising a drain, a source and a gate;
   an interconnecting structure, electrically connected to the n-type transistors, and comprising:
a common anode, electrically connected to the sources of the n-type transistors;
vias, each being electrically connected to a drain of one n-type transistor;
b) forming a set of anode layers and a set of electrical contact pads on the interconnecting structure, the anode layers being spaced apart from one another so as to form a network of rows and of columns, each anode layer being electrically connected to the common anode, each electrical contact pad being adjacent to one anode layer and being electrically connected to one via;
c) forming a set of stacks of organic semiconductor layers, each stack of organic semiconductor layers extending over one anode layer and around said anode layer, at distance from the electrical contact pad adjacent to said anode layer;
d) forming a cathode layer extending over the interconnecting structure, over the set of stacks of organic semiconductor layers and over the set of electrical contact pads;
e) successively forming a capping layer and an encapsulating layer on the cathode layer;
f) locally etching the encapsulating layer, the capping layer and the cathode layer so as to electrically isolate the anode layers from one another and to form a matrix array of pixels, each pixel comprising one anode layer and one electrical contact pad adjacent to said anode layer.

In other words, step b) consists in forming a set of anode layers and a set of electrical contact pads on a surface of the interconnecting structure, the anode layers being spaced apart from one another so as to form a network of rows and of columns, each anode layer being electrically connected to the common anode, each electrical contact pad being adjacent to one anode layer and being electrically connected to one via.

In other words, step d) consists in forming a cathode layer extending over the surface of the interconnecting structure, over the set of stacks of organic semiconductor layers and over the set of electrical contact pads.

In other words, step f) consists in locally etching the encapsulating layer, the capping layer and the cathode layer until the surface of the interconnecting structure is reached, so as to electrically isolate the anode layers therebetween from the cathode layer and to form a matrix array of pixels, each pixel comprising one anode layer and one electrical contact pad adjacent to said anode layer.

Thus, such a process according to the invention allows a direct (i.e. non-inverted) common-anode architecture to be preserved, the cathode being located above the anode in the stack. The process according to the invention makes it possible, by virtue of step f), to singulate the cathode at the pixel scale even though it is very difficult, or even impossible, to deposit a cathode locally on a stack of organic semiconductor layers corresponding to one pixel, in particular when pitch is less than or equal to 10 μm. Each pixel may be driven via the corresponding electrical contact pad. Burn-in is decreased compared to the prior art by virtue of this singulation of the cathode at the pixel scale, which makes it possible to attenuate crosstalk between adjacent pixels.

The process according to the invention may comprise one or more of the following features.

According to one feature of the invention, step f) is executed by ion beam etching.

According to one feature of the invention, step f) is preceded by a step of forming a photosensitive etch mask on the encapsulating layer formed in step e), the photosensitive etch mask being suitable for defining the matrix array of pixels.

According to one feature of the invention, step b) is executed so that the network of rows and of columns has a pitch less than or equal to 10 μm.

According to one feature of the invention, step f) forms etched regions; and step f) is followed by a step g) of filling the etched regions with an encapsulating material, preferably alumina Al₂O₃.

Thus, one procured advantage is that the pixels are protected from air and moisture.

According to one feature of the invention, step e) is executed so that the capping layer is made of silicon monoxide SiO.

According to one feature of the invention, step e) is executed so that the encapsulating layer is made of alumina Al₂O₃.

According to one feature of the invention, step d) is executed so that the cathode layer is made of silver Ag.

According to one feature of the invention, steps d) and e) are executed so that the cathode layer, the capping layer and the encapsulating layer have a total thickness of 75 nm or less.

Thus, one procured advantage is that the etch of step f) is facilitated.

According to one feature of the invention:
step c) is executed with a shadow mask;
step d) is executed without a shadow mask.

Thus, one procured advantage is in particular that maintenance problems related to particulate contamination caused by manipulation of shadow masks are reduced.

According to one feature of the invention, step c) is followed by a step of removing the shadow mask in an inert atmosphere.

### Definitions

By “substrate”, what is meant is a self-supporting physical carrier made of a base material from which an electroluminescent device is able to be formed. A substrate may be a wafer, generally taking the form of a disc obtained by cutting an ingot of a crystalline material.
By “stack” what is meant is a succession of layers in a vertical direction (i.e. along the normal to the surface of the substrate on which the interconnecting structure is formed).
By “interconnecting structure”, what is meant is a stack of interconnect levels comprising metal tracks embedded in a dielectric. An interconnecting structure is conventionally formed on the substrate by a BEOL manufacturing unit (BEOL standing for Back-End-Of-Line).
By “common anode”, what is meant is an anode intended to be common to all the pixels.
By “via”, what is meant is a metallized hole allowing an electrical connection to be made, in particular between interconnect levels.
By “cathode layer”, what is meant is a layer suitable for forming a cathode, i.e. an electrode that donates electrons when the electroluminescent device is biased.
By “anode layer”, what is meant is a layer suitable for forming an anode, i.e. an electrode that donates holes (or receives electrons) when the electroluminescent device is biased.
By “capping layer”, what is meant is a layer the refractive index and thickness of which are suitable for optimizing extraction of light from the electroluminescent device.
By “encapsulating layer”, what is meant is a layer suitable for protecting the electroluminescent device from air and moisture.
The term “shadow mask” is also known as a “stencil”.

### BRIEF DESCRIPTION OF THE DRAWINGS

Other features and advantages will become apparent from the detailed description of various embodiments of the invention, the description containing examples and references to the appended drawings.

FIG. 1 is a schematic cross-sectional view illustrating step a) of a process according to the invention.

FIG. 2 is a schematic cross-sectional view illustrating step b) of a process according to the invention.

FIG. 3 is a schematic cross-sectional view illustrating step c) of a process according to the invention. For the sake of simplicity, each stack of organic semiconductor layers has been represented by a single layer.

FIG. 4 is a schematic cross-sectional view illustrating step d) of a process according to the invention.

FIG. 5 is a schematic cross-sectional view illustrating step e) of a process according to the invention. For the sake of simplicity, the capping layer and the encapsulating layer have been represented by a single layer.

FIG. 6 is a schematic cross-sectional view illustrating a step of forming a photosensitive etch mask preceding step f).

FIG. 7 is a schematic cross-sectional view illustrating step f) of a process according to the invention with the etch mask illustrated in FIG. 6.

FIG. 8 is a schematic cross-sectional view illustrating step g) of a process according to the invention following step f) illustrated in FIG. 7.

It should be noted that, for the sake of legibility and ease of understanding, the drawings described above are schematic, and not necessarily to scale. The cross sections are cut normal to the surface of the substrate on which the interconnecting structure is formed.

### DETAILED DESCRIPTION OF EMBODIMENTS

For the sake of simplicity, elements that are identical or that perform the same function in the various embodiments have been designated with the same references.

One subject of the invention is a process for manufacturing an organic electroluminescent device, comprising steps of:
a) using a stack comprising, in succession:
   a substrate 1, incorporating n-type thin-film transistors 10 each comprising a drain D, a source S and a gate G;
   an interconnecting structure 2, electrically connected to the n-type transistors 10, and comprising:
a common anode 20, electrically connected to the sources S of the n-type transistors 10;
vias 21, each electrically connected to a drain D of one n-type transistor 10;
b) forming a set of anode layers 3 and a set of electrical contact pads 4 on the interconnecting structure 2, the anode layers 3 being spaced apart from one another so as to form a network of rows and of columns, each anode layer 3 being electrically connected to the common anode 20, each electrical contact pad 4 being adjacent to one anode layer 3 and being electrically connected to one via 21;
c) forming a set of stacks 5 of organic semiconductor layers, each stack 5 of organic semiconductor layers extending over one anode layer 3 and around said anode layer 3, at distance from the electrical contact pad 4 adjacent to said anode layer 3;
d) forming a cathode layer 6 extending over the interconnecting structure 2, over the set of stacks 5 of organic semiconductor layers and over the set of electrical contact pads 4;
e) successively forming a capping layer 7 and an encapsulating layer 8 on the cathode layer 6;
f) locally etching the encapsulating layer 8, the capping layer 7 and the cathode layer 6 so as to electrically isolate the anode layers 3 from one another and to form a matrix array of pixels, each pixel comprising one anode layer 3 and one electrical contact pad 4 adjacent to said anode layer 3.

### Step a)

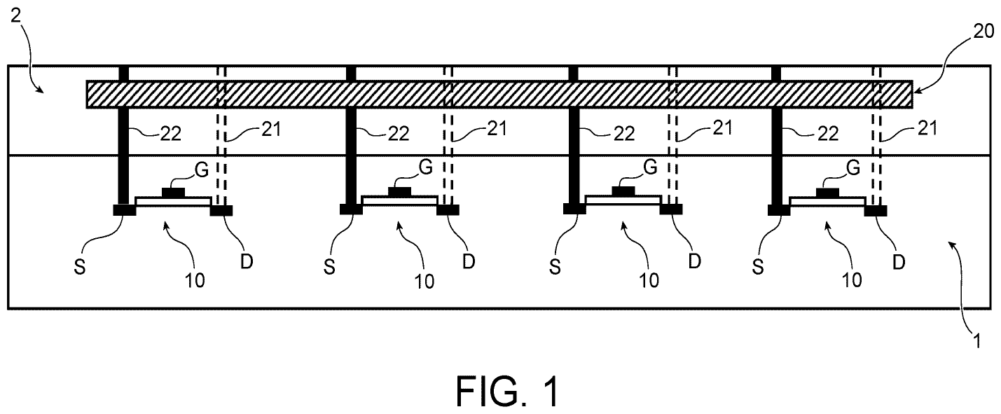

Step a) is illustrated in FIG. 1.

Step a) consists in using a stack comprising, in succession:
a substrate 1, incorporating n-type thin-film transistors 10 each comprising a drain D, a source S and a gate G;
an interconnecting structure 2, electrically connected to the n-type transistors 10, and comprising:
a common anode 20, electrically connected to the sources S of the n-type transistors 10;
vias 21, each being electrically connected to a drain D of one n-type transistor 10.

By way of non-limiting example, the substrate 1 may be made of silicon.

The n-type thin-film transistors (TFTs) possess a channel that may be made of:
a transparent conducting oxide (TCO),
a transparent semiconducting oxide (TSO) such as indium-gallium-zinc (In—Ga—Zn) oxide (IGZO).

In particular, IGZO exhibits better stability under the current used to drive organic electroluminescent devices such as OLED microdisplays. By “microdisplay”, what is meant is a display each pixel of which has an area less than or equal to 30 μm by 30 μm.

The n-type thin-film transistors 10 are advantageously arranged so as to form a 2T-1C pixel supply and addressing scheme, i.e. two TFTs and one capacitor are used to drive one pixel.

The common anode 20 is electrically connected to the sources S of the n-type transistors 10, preferably by additional vias 22. The common anode 20 is advantageously buried within the interconnecting structure 2. The common anode 20 may be made of a metal. By way of non-limiting example, the metal may comprise a first layer of an aluminium-copper (Al—Cu) alloy and a second layer of titanium nitride TiN.

When the substrate 1 is made of silicon, the vias 21 and the additional vias 22 may be through-silicon vias (TSVs).

### Step b)

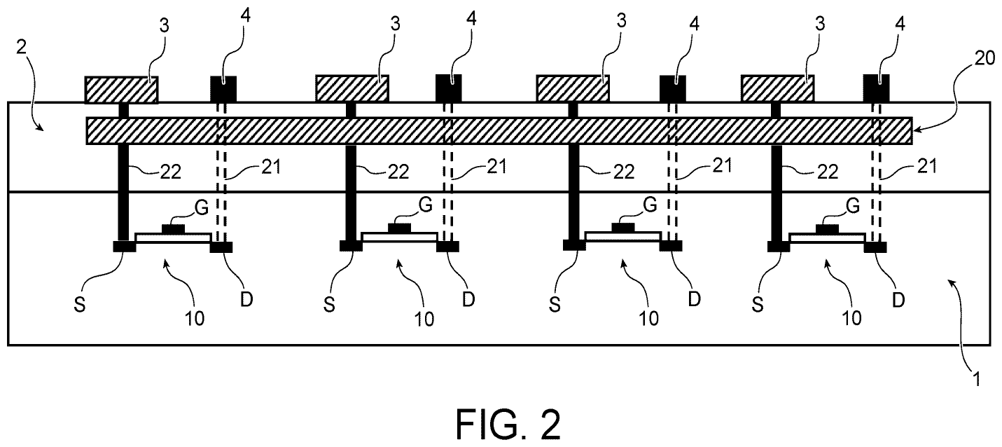

Step b) is illustrated in FIG. 2.

Step b) consists in forming a set of anode layers 3 and a set of electrical contact pads 4 on the interconnecting structure 2, the anode layers 3 being spaced apart from one another so as to form a network of rows and of columns. In other words, step b) consists in forming a set of anode layers 3 and a set of electrical contact pads 4 on a surface of the interconnecting structure 2, the anode layers 3 being spaced apart from one another so as to form a network of rows and of columns.

The set of anode layers 3 and the set of electrical contact pads 4 may be deposited simultaneously on the interconnecting structure 2 (last metallization level), for example by physical vapour deposition. Next, the set of anode layers 3 and the set of electrical contact pads 4 may be formed (i.e. defined) by photolithography, for example using a photoresist that will then be stripped. The set of anode layers 3 and the set of electrical contact pads 4 may be made of a metal. By way of non-limiting example, the metal may comprise a first layer of an aluminium-copper (Al—Cu) alloy and a second layer of titanium nitride TiN. Each anode layer 3 is electrically connected to the common anode 20, preferably by the additional vias 22. Each electrical contact pad 4 is adjacent to one anode layer 3 and is electrically connected to one via 21. Each electrical contact pad 4 is therefore connected to a drain D of one n-type transistor 10.

Step b) is advantageously executed so that the network of rows and of columns has a pitch (i.e. spatial period) less than or equal to 10 μm.

### Step c)

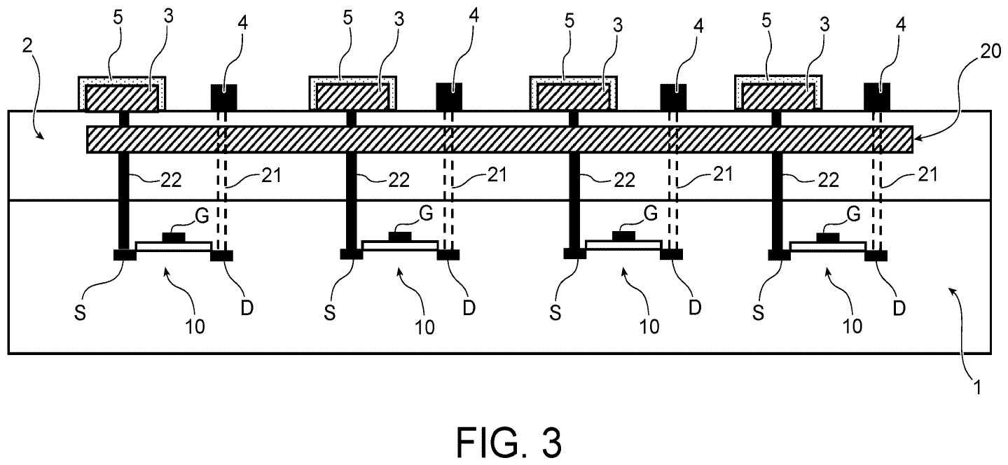

Step c) is illustrated in FIG. 3.

Step c) consists in forming a set of stacks 5 of organic semiconductor layers, each stack 5 of organic semiconductor layers extending over one anode layer 3 and around said anode layer 3, at distance from the electrical contact pad 4 adjacent to said anode layer 3.

By way of non-limiting example, each stack 5 of organic semiconductor layers may comprise, in succession:
a hole injection layer (HIL) formed on the anode layer 3;
a hole transport layer (HTL);
an emissive layer (EML);
an electron transport layer (ETL);
an electron injection layer (EIL).

As a variant, each stack 5 of organic semiconductor layers may comprise, in succession:
an HIL formed on the anode layer 3;
an HTL;
an EML;
a hole blocking layer (HBL);
an ETL.

Step c) may be executed with a shadow mask. Step c) is advantageously followed by a step consisting in removing the shadow mask in an inert atmosphere, for example one based on dinitrogen N₂ or argon Ar.

The stacks 5 of organic semiconductor layers may be formed using a deposition technique known to those skilled in the art, for example a physical vapour deposition (PVD). By way of non-limiting example, each stack 5 of organic semiconductor layers may have a thickness of the order of 100 nm.

### Step d)

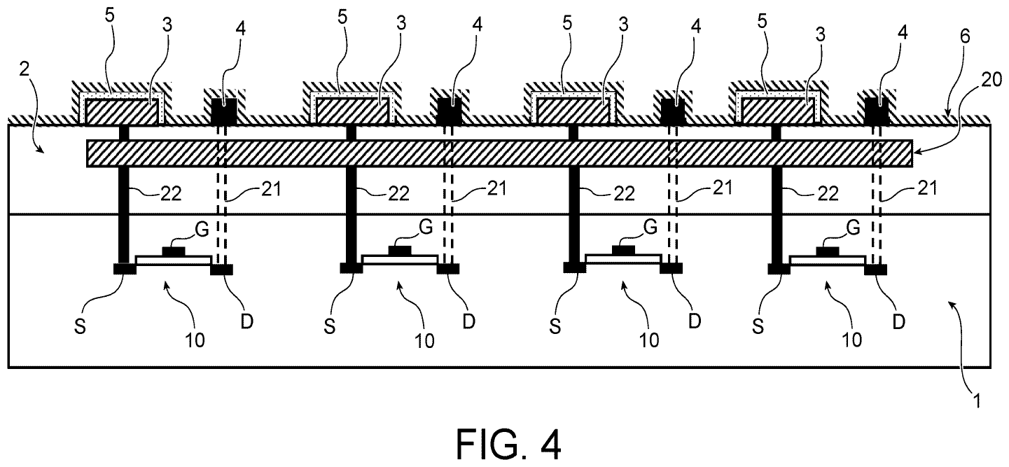

Step d) is illustrated in FIG. 4.

Step d) consists in forming a cathode layer 6 extending over the interconnecting structure 2, over the set of stacks 5 of organic semiconductor layers and over the set of electrical contact pads 4. In other words, step d) consists in forming a cathode layer 6 extending over the surface of the interconnecting structure 2, over the set of stacks 5 of organic semiconductor layers and over the set of electrical contact pads 4.

Step d) is advantageously executed so that the cathode layer 6 is made of a metal, preferably silver Ag. By way of non-limiting example, the cathode layer 6 may have a thickness of the order of 15 nm.

Step d) is advantageously executed without a shadow mask. In other words, the cathode layer 6 is formed by a wafer-level type deposition.

### Step e)

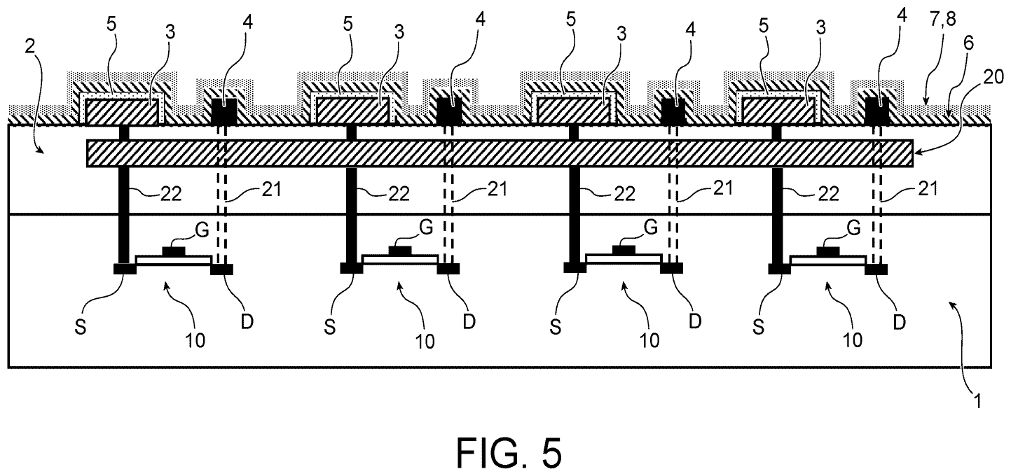

Step e) is illustrated in FIG. 5.

Step e) consists in successively forming a capping layer 7 and an encapsulating layer 8 on the cathode layer 6.

Step e) is advantageously executed so that the capping layer 7 is made of silicon monoxide SiO. By way of non-limiting example, the capping layer 7 may be formed on the cathode layer 6 by PVD. The capping layer 7 is electrically insulating. By way of non-limiting example, the capping layer 7 may have a thickness of the order of 25 nm.

Step e) is advantageously executed so that the encapsulating layer 8 is made of alumina Al₂O₃. The encapsulating layer 8 made of alumina Al₂O₃ is preferably formed on the capping layer 7 by atomic layer deposition (ALD). The encapsulating layer 8 is electrically insulating. By way of non-limiting example, the encapsulating layer 8 may have a thickness of the order of 25 nm.

Steps d) and e) are advantageously executed so that the cathode layer 6, the capping layer 7 and the encapsulating layer 8 have a total thickness of 75 nm or less.

### Step f)

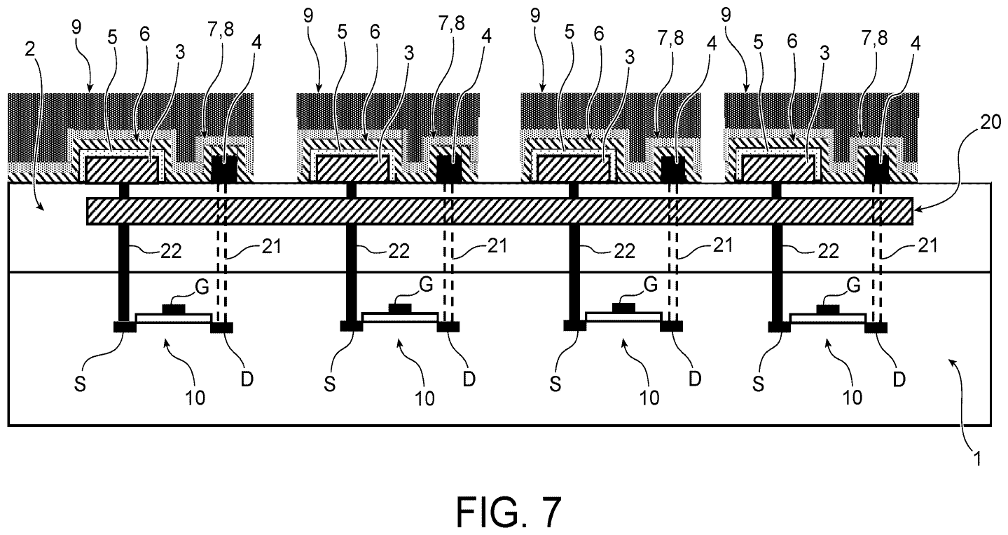

Step f) is illustrated in FIG. 7.

Step f) consists in locally etching the encapsulating layer 8, the capping layer 7 and the cathode layer 6 so as to electrically isolate the anode layers 3 from one another and to form a matrix array of pixels. In other words, step f) consists in locally etching the encapsulating layer 8, the capping layer 7 and the cathode layer 6 until the surface of the interconnecting structure 2 is reached, so as to electrically isolate the anode layers 3 therebetween from the cathode layer 6 and to form a matrix array of pixels. Each pixel comprises an anode layer 3 and an electrical contact pad 4 adjacent to said anode layer 3.

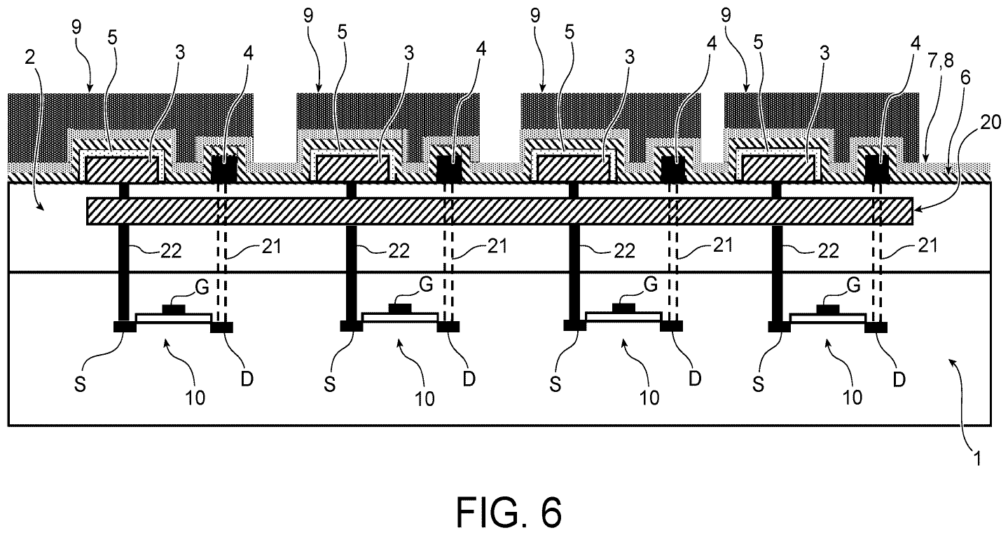

As illustrated in FIG. 6, step f) is advantageously preceded by a step of forming a photosensitive etch mask 9 on the encapsulating layer 8 formed in step e), the photosensitive etch mask 9 being suitable for defining the matrix array of pixels. By way of non-limiting example, the etch mask 9 may be a photoresist such as a resist denoted JSR (e.g. JSR 420) marketed by JSR. The photosensitive etch mask 9 is made of an electrically insulating material. The photosensitive etch mask 9 is advantageously preserved at the end of step f). By way of non-limiting example, the photosensitive etch mask 9 may have a thickness of the order of 1.5 μm.

Step f) is advantageously executed so that the set of electrical contact pads 4 is not exposed at the end of the etch. More precisely, the photosensitive etch mask 9 (illustrated in FIG. 6) is designed so that the set of electrical contact pads 4 is not exposed at the end of the etch.

Step f) is advantageously executed by ion beam etching (IBE). The parameters of the IBE etch, in particular the energy of the ions, the directivity of the ions and the density of the ion beam, will be adjusted by a person skilled in the art depending on the thickness and the nature of the materials of the cathode layer 6, of the capping layer 7 and of the encapsulating layer 8.

By way of non-limiting example, when the cathode layer 6 is made of silver Ag, the capping layer 7 is made of silicon monoxide SiO and the encapsulating layer 8 is made of alumina Al₂O₃, the total thickness of these layers 6, 7, 8 not exceeding 75 nm, it is possible to execute an IBE etch with an ion directivity of −5° and an ion beam current of 200 mA.

### Step g)

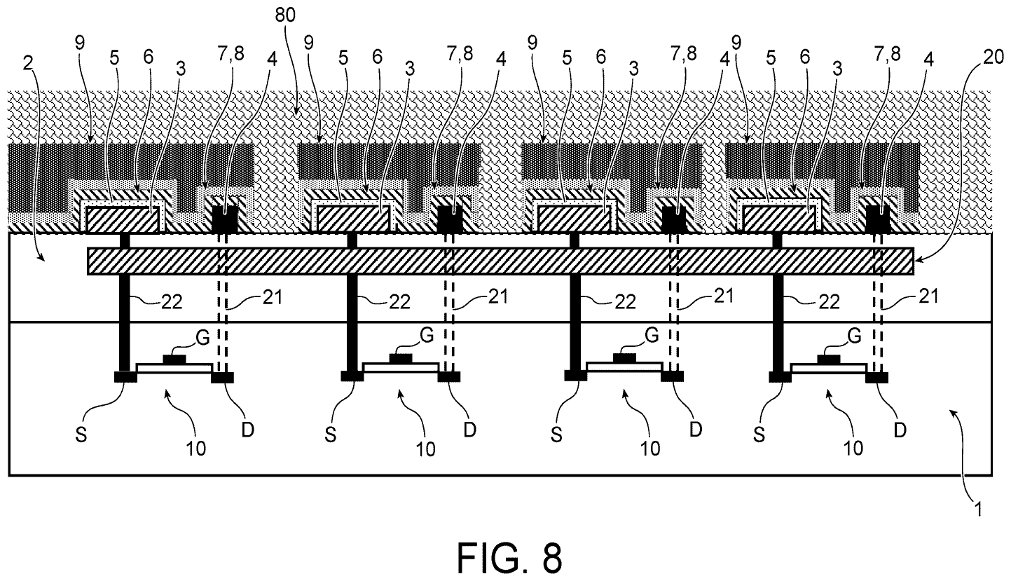

Step g) is illustrated in FIG. 8.

Step f) is advantageously followed by a step g) consisting in filling the regions etched in step f) with an encapsulating material 80, preferably alumina Al₂O₃. Step g) is advantageously executed so as to form a super high barrier (SHB). The encapsulating material 80 is electrically insulating.

The invention is not limited to the disclosed embodiments. Anyone skilled in the art will be able to consider technically workable combinations thereof, and to substitute equivalents therefor.

1. A process for manufacturing an organic electroluminescent device, comprising steps of:
a) using a stack comprising, in succession:
a substrate, incorporating n-type thin-film transistors each comprising a drain, a source and a gate;
an interconnecting structure, electrically connected to the n-type thin-film transistors, and comprising:
a common anode, electrically connected to the sources of the n-type thin-film transistors;
vias, each electrically connected to a drain of one n-type thin-film transistor;
b) forming a set of anode layers and a set of electrical contact pads on a surface of the interconnecting structure, the anode layers being spaced apart from one another so as to form a network of rows and of columns, each anode layer being electrically connected to the common anode, each electrical contact pad being adjacent to one anode layer and being electrically connected to one via;
c) forming a set of stacks of organic semiconductor layers, each stack of organic semiconductor layers extending over one anode layer and around said anode layer, at distance from an electrical contact pad adjacent to said anode layer;
d) forming a cathode layer extending over the surface of the interconnecting structure, over the set of stacks of organic semiconductor layers and over the set of electrical contact pads;
e) successively forming a capping layer and an encapsulating layer on the cathode layer;
f) locally etching the encapsulating layer, the capping layer and the cathode layer until the surface of the interconnecting structure is reached, so as to electrically isolate the anode layers therebetween from the cathode layer and to form a matrix array of pixels, each pixel comprising one anode layer and one electrical contact pad adjacent to said anode layer.

2. The process according to claim 1, wherein step f) is executed by ion beam etching.

3. The process according to claim 1, wherein step f) is preceded by a step of forming a photosensitive etch mask on the encapsulating layer formed in step e), the photosensitive etch mask being designed to define the matrix array of pixels.

4. The process according to claim 1, wherein step b) is executed so that the network of rows and of columns has a pitch less than or equal to 10 μm.

5. The process according to claim 1, wherein step f) forms etched regions; and step f) is followed by a step g) of filling the etched regions with an encapsulating material.

6. The process according to claim 1, wherein step e) is executed so that the capping layer is made of silicon monoxide SiO.

7. The process according to claim 1, wherein step e) is executed so that the encapsulating layer is made of alumina Al₂O₃.

8. The process according to claim 1, wherein step d) is executed so that the cathode layer is made of silver Ag.

9. The process according to claim 1, wherein steps d) and e) are executed so that the cathode layer, the capping layer and the encapsulating layer have a total thickness of 75 nm or less.

10. The process according to claim 1, wherein:
step c) is executed with a shadow mask;
step d) is executed without a shadow mask.

11. The process according to claim 10, wherein step c) is followed by a step of removing the shadow mask in an inert atmosphere.
